(19) United States
(12) Patent Application Publication
(10) Pub. No.: US 2024/0133016 A1
(43) Pub. Date: Apr. 25, 2024

(54) A METHOD FOR ETCHING MOLYBDENUM

(71) Applicants: IMEC VZW, Leuven (BE); SCREEN HOLDINGS CO., LTD., Kyoto (JP)

(72) Inventors: Antoine Pacco, Mechelen (BE); Nakano Teppei, Woluwe-Saint-Pierre (BE)

(73) Assignees: IMEC VZW, Leuven (BE); SCREEN HOLDINGS CO., LTD., Kyoto (JP)

(21) Appl. No.: 18/547,477

(22) PCT Filed: Feb. 24, 2021
(86) PCT No.: PCT/EP2021/054490

§ 371 Date: Aug. 21, 2023

(51) Int. Cl. C23C 8/80; C23C 8/12

(52) U.S. Cl. CPC C23C 8/80; C23C 8/12

(57) ABSTRACT

The disclosure relates to a method for etching a molybdenum feature, comprising the steps of: a) oxidizing a thickness portion of the molybdenum feature using a thermal oxidation process to form a thermal molybdenum oxide layer, and b) dissolving the thermal molybdenum oxide layer using a wet chemistry.

### TECHNICAL FIELD

The present disclosure relates to a method for etching molybdenum.

### BACKGROUND

Integrated circuit fabrication processes typically involve recessing of metals by etching to form features, such as interconnects and contacts. Realization of some advanced interconnects may involve recessing metals in vias or trenches to form features such as fully self-aligned vias (FSAV) or buried power rails (BPR). The realization of advanced memory architectures may involve recessing of word-line or gate metal. Tungsten (W) is a commonly used metal in current technology. Tungsten may be deposited using chemical vapor deposition (CVD) or atomic layer deposition (ALD) and recessed with plasma or wet-chemical etching solutions.

Molybdenum (Mo) is a promising candidate to succeed tungsten in applications such as the aforementioned. Molybdenum has lower resistivity at smaller critical dimensions compared to metals like tungsten and copper. Lower resistivity enables maintaining overall device performance during scaling. Molybdenum further has electromigration properties which allows barrier-less integration.

However, molybdenum etching in various wet etching solutions (steady state or continuous) results in roughening of the surface, resulting in an undesired surface state, e.g. for subsequent process step. This is illustrated in FIG. 1 depicting conventional continuous wet chemical etching of (left) an Mo film (PVD deposited and annealed in N₂ at 420° C.), (center) in ozonated water (60 seconds in deionized water, DIW, with about 10 ppm O₃) and (right) in a hydrogen peroxide solution (90 seconds in DIW with 10% H₂O₂). In addition to inadequate control of etch depth (“RS depth”), both solutions may as shown create considerable surface roughening of the molybdenum surface and residues.

SUMMARY In light of the above, it is an objective to provide an improved method for etching molybdenum with less surface roughening than conventional wet etching solutions. It is a further or alternative objective to enable etching of molybdenum with an increased control over etch depth (i.e. controlled recessing of molybdenum).

According to an aspect there is provided a method for etching a molybdenum feature. The method comprises the steps of:
a) oxidizing a thickness portion of the molybdenum feature using a thermal oxidation process to form a thermal molybdenum oxide layer, and
b) dissolving the thermal molybdenum oxide layer using a wet chemistry. The etching method enables etch back of a surface of a molybdenum feature without causing any appreciable increase in surface roughness. Hence, an initially smooth molybdenum surface may be etched in accordance with the method to form a recessed/etched-back surface with preserved smoothness. Indeed, the etching method may even contribute to reducing a roughness of a molybdenum surface. The etching method further enables an improved control over etch depth, e.g. on the order of nanometers. Accordingly, the etching method may advantageously be used for partial etch back of a molybdenum surface, i.e. such that a thickness portion of the molybdenum feature is preserved when the etching is stopped, e.g. as in controlled recessing of a molybdenum feature.

The thermal oxidation process allows a surface of the molybdenum feature exposed to the oxidizing ambient to be oxidized in a conformal manner. The thermal molybdenum oxide layer may hence be formed with a uniform thickness. Conversely, this implies that a uniformly thick thickness portion of the molybdenum feature may be oxidized, i.e. oxidation may extend to a uniform depth into the molybdenum feature.

It is contemplated that thermal oxidation of molybdenum is diffusion limited and (at least) primarily occurs at the oxide-metal interface. This may confer a self-limiting property to the thermal oxidation process, which may further facilitate control over etch depth. That is, due to the self-limiting property the thermally-driven molybdenum oxide growth will tend to plateau at a maximum thickness after a certain duration, the maximum thickness and the duration both being functions of process parameters which may be readily controlled, such as temperature, concentration and flow of the oxidizing ambient.

Step a) of the method may accordingly comprise oxidizing a thickness portion of the molybdenum feature using a thermal oxidation process to form a thermal molybdenum oxide layer of a self-limiting thickness. The etching method hence facilitates a step-wise etching, like atomic layer etching (ALE), wherein the molybdenum feature may be recessed in one or more steps until a desired depth is achieved.

A thermal oxidation may promote formation of MoO₃ (molybdenum trioxide) such that at least a major portion of the thermal molybdenum oxide layer may be formed by MoO₃. Depending on process conditions the thermal molybdenum oxide layer however comprise additional suboxides like MoOx_{(x>2)}. If native oxide (typically comprising MoO₂) is present on the (metallic) surface of the molybdenum feature exposed to the oxidizing ambient the native oxide may be converted to MoO₃.

By step b) of the etching method, the thermal molybdenum oxide may be dissolved and thus removed from a recessed/etched back surface of the molybdenum feature. Thermal molybdenum oxide may be quickly dissolved using a wet chemistry, i.e. a liquid-phase molybdenum oxide dissolution chemistry. A wet chemistry may allow dissolving the thermal molybdenum oxide layer such that the thermal molybdenum oxide layer may be selectively removed from the molybdenum feature. By “selectively removed” is hereby meant that the thermal molybdenum oxide layer may be removed without causing any appreciable oxidation or etching of the molybdenum feature. As will be set out below in connection with various embodiments, several suitable wet chemistries exist. For example, MoO₃ is highly water dissolvable which makes the method compatible with various water-comprising inexpensive wet chemistries typically used in semiconductor processing. Hence, according to some embodiments the wet chemistry may be a water-comprising liquid.

The method can be applied for etching molybdenum features of different aspect ratio and orientations (vertical as well as lateral etching). Accordingly, the term “thickness portion” is used herein to refer to a portion of the molybdenum feature extending from the metal-oxide interface into the molybdenum feature in a direction transverse to said interface.

According to some embodiments, an oxidizing ambient of the thermal oxidation process may be O₃ (ozone gas). Ozone gas as an oxidizing agent may promote formation of MoO₃ to a greater extent than both conventional wet etchants as well as gaseous oxidizing agents like O₂. O₃ may additionally allow thermal oxidation to occur at a relatively low activation temperature.

Using ozone gas, the thermal oxidation process may comprise heating the molybdenum feature to a temperature of at least 150° C. A temperature of 150° C. or above may promote growth of MoO₃ at a rate and to a thickness enabling recessing in a time-efficient manner. A temperature in in a range from 180 to 300° C. may further promote growth of a thermal oxide with a high proportion of MoO₃. In this temperature range, the self-limiting thickness of the thermal molybdenum oxide layer may be 6 nm or less.

A concentration of the ozone gas may be at least 50 g/m³. An O₃ concentration may be in a range from 100 to 200 g/m³.

An O₃ flow rate may be at least 5 SLM. An O₃ flow rate is in a range from 18 to 20 SLM.

O₃ concentration and/or flow rate in these ranges allows reactants to be supplied towards the molybdenum surface in an amount promoting a quick and reliable growth of MoO₃. Although thermal oxidation may be observed also outside these parameter ranges, one or more of these process conditions may improve the rate and reliability of the thermal oxidation process.

The thermal oxidation process may comprise subjecting the molybdenum feature to the oxidizing ambient (ozone gas) for a duration of at least 30 seconds. This duration has been observed to allow obtaining a thermal molybdenum oxide layer of a self-limiting thickness, as discussed above.

According to some embodiments, the thermal oxidation process may comprise heating the molybdenum feature to a temperature in a range from 180 to 300° C., in an oxidizing ambient with an O₃ concentration in a range from 100 to 200 g/m³, and an O₃ flow rate in a range from 18 to 20 SLM, for a duration of 30 to 300 seconds.

According to some embodiments, an oxidizing ambient of the thermal oxidation process may instead be O₂ (oxygen, i.e. in gas-phase). Using oxygen as the oxidizing agent may reduce requirements on the process equipment and allow a cost-effective realization of molybdenum etching.

Using oxygen, the thermal oxidation process may comprise heating the molybdenum feature to a temperature of at least 200° C. At 200° C. there may be an onset of oxidation of the molybdenum.

According to some embodiments, the wet chemistry may be a water-comprising liquid removing the thermal molybdenum oxide selectively to molybdenum.

The wet chemistry may be selected from an alkaline solution, DIW, or an aqueous solution of ammonia (i.e. an ammonia solution), CO₂W, HF or HCl.

DIW and an ammonia solution (e.g. NH4OH) are low-cost wet chemicals allowing quick dissolution of MoO₃ while being benign to the molybdenum surface. NH4OH may further contribute to a clean molybdenum surface by enabling repulsion of contaminating particles.

According to some embodiments, the method may comprise repeating the sequence of steps a) and b) a number of times. The step-wise etching may hence be put to use to approach the desired etch depth in a step-wise fashion.

According to some embodiments, the method may further comprise a step of pre-cleaning to remove a native oxide from the molybdenum feature prior to performing steps a) and b).

A pre clean step may remove the native molybdenum oxide such that a metallic surface of the molybdenum feature may be exposed to be directly contacted with the oxidizing ambient of the thermal oxidation process. A maximum thickness of the thermal molybdenum oxide layer obtainable during a first application of step a) may thereby be increased, allowing a greater amount of etching in a single sequence of steps a) and b). The native oxide may otherwise inhibit the thermal oxidation. A preclean step may additionally contributed to a further improved a uniformity of the thickness of the thermal molybdenum oxide layer.

### BRIEF DESCRIPTION OF THE DRAWINGS

The above, as well as additional objects, features and advantages, may be better understood through the following illustrative and non-limiting detailed description, with reference to the appended drawings. In the drawings like reference numerals will be used for like elements unless stated otherwise.

FIG. 1 illustrates molybdenum etching using conventional continuous wet etching, as a comparative example.

FIG. 2 schematically illustrates a method of etching a molybdenum feature according to an embodiment.

FIG. 3 shows XTEM images of a molybdenum film as deposited (top left), after thermal oxidation (top right and bottom left), and after an oxide dissolution step (bottom right).

FIG. 4 shows an example of a repeated cycle of thermal oxidation and wet-chemistry oxide dissolution.

FIG. 5 is an example comparison of thickness of a PVD molybdenum film without (FIG. 5a) and with (FIG. 5b) performing a pre-cleaning step.

FIG. 6 compares roughness of a molybdenum surface after being subjected to different processes conditions.

FIG. 7 illustrates recess amount of ALD and PVD molybdenum films as a function of number of cycles of thermal oxidation and oxide dissolution.

### DETAILED DESCRIPTION

The present invention relates in an aspect to a method of etching a molybdenum feature comprising a step of a) oxidizing a thickness portion of the molybdenum feature using a thermal oxidation process to form a thermal molybdenum oxide layer, and dissolving the thermal molybdenum oxide layer using a wet chemistry. This sequence of steps a) and b) can optionally be repeated (ALE style) to obtain a desired etch amount.

The molybdenum feature may be any feature/structure of molybdenum typically used in integrated circuit fabrication, such as a (thin) film, a layer, a horizontal or vertical interconnect e.g. of a back-end-of-line structure such as a conductive line or via, a buried power rail, a contact e.g. of a semiconductor device such as source/drain contact or gate.

The molybdenum feature may e.g. be formed of molybdenum deposited using PVD, CVD or ALD, or using any other conventional deposition process allowing deposition of molybdenum of high material quality. The deposited molybdenum may be annealed (e.g. in an inert atmosphere such as N₂). An anneal may improve properties of the deposited molybdenum such as the resistivity. The molybdenum deposition may be followed by process steps (e.g. conventional lithography and etching patterning techniques) for defining an initial shape of the molybdenum feature, which is to be etched.

The molybdenum feature may be arranged on a substrate. The substrate may be a semiconductor substrate of a conventional type, e.g. a Si-substrate, a Ge-substrate, a SiGe substrate, a silicon-on-insulator substrate etc.) or some other known type of substrate suitable for the type of integrated circuit device of which the molybdenum feature is to form part.

FIG. 2 schematically illustrates a method 100 of etching a molybdenum feature 10. Reference sign 10a indicates a metallic surface of the molybdenum feature 10 which is to be etched back or recessed. The direction R indicates the direction along with the surface 10a will be recessed, and may hence be referred to as recess direction R. The direction R is oriented perpendicular to the surface 10a and into the molybdenum feature 10. The dashed horizontal line indicates a geometrical plane defined by the surface 10a prior to the etching, thus representing a reference surface with respect to which the surface 10a will be recessed.

The first row of FIG. 2 shows a progression of step a) of forming of a thermal molybdenum oxide layer 14 by oxidizing a thickness portion of the molybdenum feature 10 using a thermal oxidation process. The thermal molybdenum oxide layer 14 may hence form a surface layer on the molybdenum feature 10. The arrow H represents supplying thermal energy to the molybdenum feature 10 by heating. The heat may be supplied via a substrate holder, and e.g. controlled via the set temperature of the substrate holder. However, thermal energy may also or alternatively be supplied via the ambient. As may be seen, a thickness portion of the molybdenum feature 10 is gradually oxidized and hence consumed such that the metallic surface 10a (i.e. defining the metal-oxide interface) is recessed in relation to the reference surface. During the oxidation one or more atomic layers of molybdenum may be oxidized.

As schematically shown, a thickness of the thermal molybdenum oxide layer 14 may typically exceed the thickness of molybdenum consumed during the oxidation. The thermal oxidation process may be performed until the thermal molybdenum oxide layer 14 reaches the self-limiting thickness (dependent on the process conditions of the thermal oxidation process). However, if a smaller amount of recess is desired the thermal oxidation process may be stopped prior to reaching the self-limiting thickness.

Prior to commencing the etching method, a native molybdenum oxide 12 may as shown be present on the surface 10a. Although depicted as a layer of uniform thickness, it is to be noted that the native oxide 22 also may be formed in a non-uniform manner, e.g. such that a thickness of the native oxide may vary along the surface 10a and/or portions of the surface 10a may be free from oxide. The native oxide 12 may comprise predominantly MoOx with x=2, but may additionally comprise sub-oxides with x=1 and x=3. The thermal oxidation process may however result in conversion of MoOx_{(x≤2)} of the native oxide 12 into MoO₃, as indicated in row a), wherein native oxide layer 12 is replaced by the thermal molybdenum oxide layer 14.

The second row of FIG. 2 shows a progression of step b) of dissolving of the thermal molybdenum oxide layer 14 using a wet chemistry, performed subsequent to step a). As may be seen, the thermal molybdenum oxide layer 14, is gradually dissolved and thus removed from the molybdenum feature 10a. The arrow W represents contacting the thermal molybdenum oxide layer 14 with the wet chemistry. The thermal molybdenum oxide layer 14 may be completely removed such that the recessed (metallic) surface 10a of the molybdenum feature 10 is revealed. However, as may be appreciated by the skilled person, the wet chemistry (e.g. a solute or a solvent thereof) may even if being relatively benign with respect to the molybdenum still cause some oxidation of the surface 10a such that also after the dissolving step b) a (thin) wet native molybdenum oxide is formed on the molybdenum surface, in FIG. 2 indicated by layer 16.

If a target recess amount/depth exceeds the amount of recessing obtainable by applying a single sequence of steps a) and b) to the molybdenum feature 10, the sequence may be repeated a number of times until reaching the target recess amount.

The thermal oxidation process may be conducted using conventional equipment as is known in the art, e.g. in a furnace for thermal oxidation.

The thermal oxidation process of step a) may be performed in an 03 (ozone gas) ambient/atmosphere. The thermal oxidation process may be performed at a temperature of at least 150° C. Although thermal oxide growth in O₃ may be observed also at lower temperatures (e.g. an onset may be observed at about 60° C.) a temperature of at least 150° C. may increase the yield of MoO₃ (which may be quickly dissolved in the wet chemistry) and allow forming of a thermal molybdenum oxide layer 14 of self-limiting thickness in a shorter time (e.g. in 30 to 300 seconds). A temperature in a range from 180 to 300° C. may further contribute to the growth rate and yield of MoO₃. For example, the self-limiting thickness of the thermal molybdenum oxide layer 14 may be 1.8 nm at a temperature of 180° C., and 6 nm at a temperature of 290° C. A concentration of O₃ may be at least 50 g/m³. An O₃ flow rate may be at least 5 SLM. For example, an O₃ concentration may be a range from 100 to 200 g/m³, and an O₃ flow rate may be in a range from 18 to 20 SLM. Although a concentration and/or flow in these ranges may provide suitable process conditions for the thermal oxidation, the temperature has been observed to have a greater impact on the thermal oxidation process. It is hence contemplated that also lower concentration and/or flow of O₃ may be used.

Alternatively, the thermal oxidation process may be performed in an O₂ (gas-phase oxygen) ambient/atmosphere. The thermal oxidation process may be performed at a temperature of at least 200° C. Although thermal oxide growth in O₂ may be observed also at lower temperatures (e.g. an onset may be observed at about 60° C.) a temperature of at least 200° C. or above may increase the yield of MoO₃ and allow forming of a thermal molybdenum oxide layer 14 of self-limiting thickness in a shorter time (e.g. 20 minutes or less).

Oxidation may for example be observed in an 02 ambient at atmospheric pressure. An O₂ flow rate may for example be 10 SLM or more. Although a concentration and/or flow in these ranges may provide suitable process conditions for the thermal oxidation, the temperature has been observed to have a greater impact on the thermal oxidation process.

After the oxidation step the substrate (with the molybdenum feature 100) may be submerged and/or rinsed with the wet chemistry, e.g. in a tank.

The wet chemistry of step b) may be a water-comprising liquid of a composition such that the thermal molybdenum oxide may be removed selectively to the molybdenum forming the metallic surface 10a. Examples of such liquids include an ammonia solution (dNH₄OH) or other aqueous solution of CO₂W, HF or HCl. A dilution ratio of the solutions may as a non-limiting example be 1:100, but smaller as well as higher dilution ratios are also possible as long it is ensured that the wet chemistry does not cause appreciable etching or oxidation of the molybdenum. However other aqueous solutions are also possible like (diluted) alkaline solutions. Other examples include DIW and UPW. It is contemplated that also non-aqueous solutions, such as an inorganic solvent, may be used.

Optionally, the sequence of step a) and b) may be preceded by a pre-cleaning step to remove a native oxide 12 from the molybdenum feature 10, as represented by arrow P in FIG. 2, first row. The native oxide 12 may if present inhibit the thermal oxidation process. The pre-cleaning may be performed by contacting the native oxide 12 with e.g. any of the above-mentioned (diluted) aqueous solutions.

Although FIG. 2 shows the surface 10a in a horizontal orientation, this does not imply that the surface 10a during the etching method needs to be horizontally oriented in an absolute sense. Indeed, the etching method may be applied to a surface 10a oriented either parallel to or at an angle with respect to the substrate (e.g. a “horizontal” top surface or a “vertical” sidewall surface of a molybdenum feature 10 for instance forming a contact or line on the substrate). It is further to be noted that two or more differently oriented surfaces of the molybdenum feature 10 may be recessed simultaneously, e.g. by exposing each of these surfaces to the etching method. It is further to be noted that in a typical wafer-scale application a plurality of like molybdenum features may be recessed simultaneously by exposing them to the etching method.

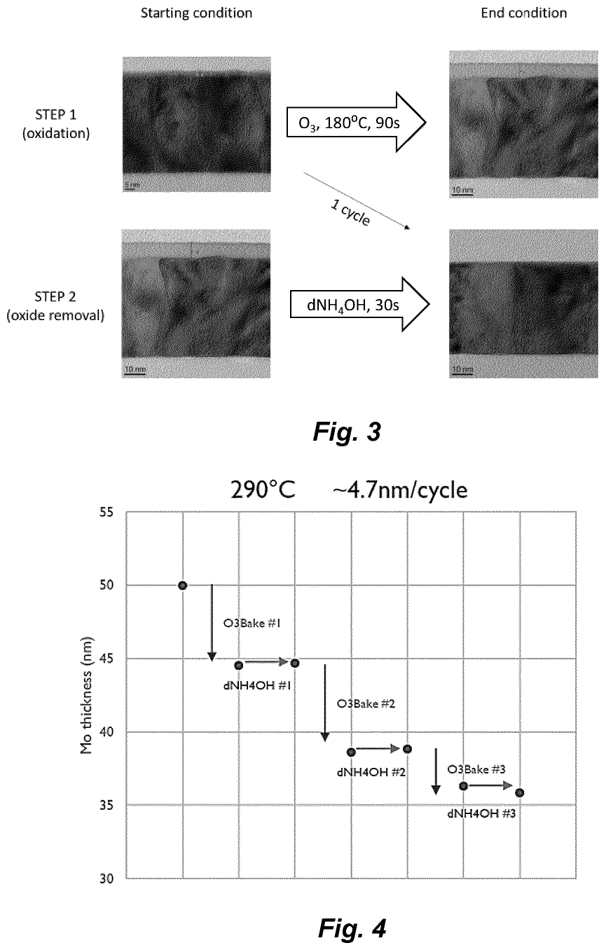

FIG. 3 cross-sectional transmission electron microscopy (XTEM) image of a molybdenum film deposited on a wafer using PVD. The molybdenum film is subjected to a single cycle of thermal oxidation (bake in an 100 g/m³ O₃ ambient with 18 SLM at 180° C. for 90 seconds) and wet-chemistry oxide dissolution (in dNH₄OH in a 1:100 dilution for 30 seconds).

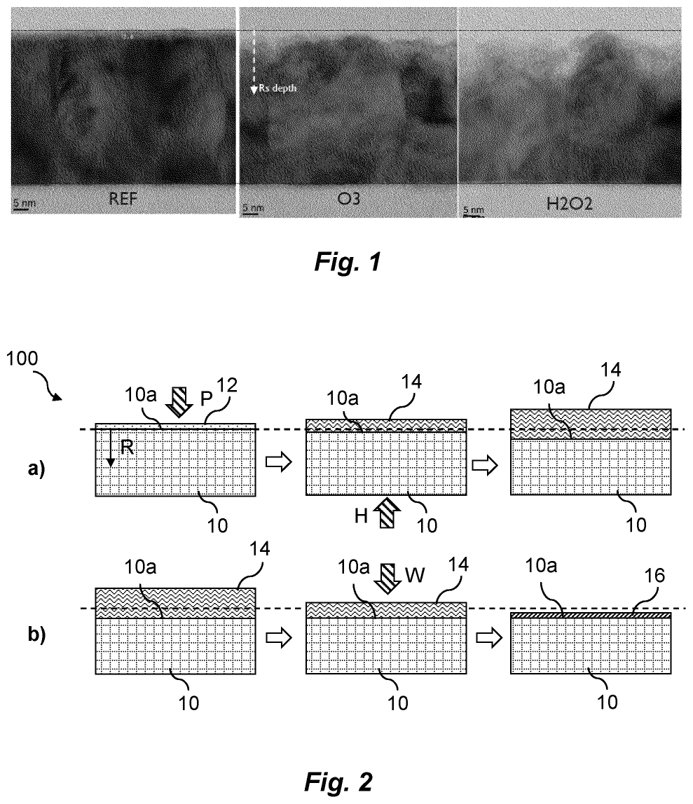

It is contemplated that the improved results in terms of surface roughness obtained in this example over the continuous wet etching results depicted in FIG. 1, in part may be attributed to an improved process uniformity since a thermal oxidation process in gas is less grain-boundary dependent and less diffusion-limited than a wet chemical oxidation process in a solution. Also, continuous wet etching of molybdenum in solution with a strong oxidizer, like hydrogen peroxide, has an electrochemical mechanism accompanied by undesirable formation of slightly soluble molybdenum hydrates that may passivate the metallic surface. A wet etch comprising conventional (strongly) acidic O3 solution may also result in MoOx(x>2) enrichment at the metal-oxide interface, at the expense of MoO3.

FIG. 4 is an example of a repeated cycle of thermal oxidation and wet-chemistry oxide dissolution, applied to a molybdenum feature (a PVD deposited film, twice annealed in N₂) with an initial thickness of 50 nm. FIG. 4 illustrates a sequence of three repeated cycles of thermal oxidation (bake in a 100 g/m³ O₃ ambient at 290° C. for 30 seconds) followed by oxide dissolution (in dNH₄OH in a 1:100 dilution for 30 seconds). The recess amount per cycle was about 4.7 nm.

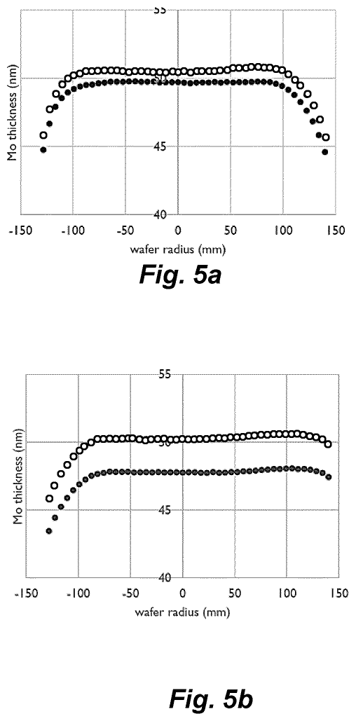

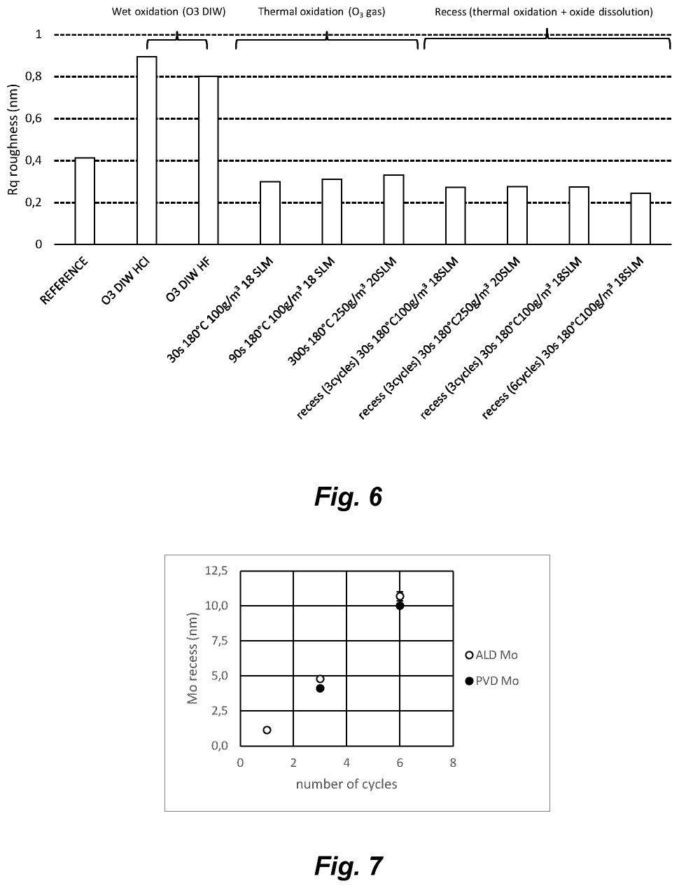

FIG. 5a shows the thickness of a PVD molybdenum film along a wafer radius before (dots with no fill) and (filled dots) after one cycle of thermal oxidation and wet-chemistry oxide dissolution, without performing a pre-clean step. FIG. 6b shows the thickness of a similar PVD molybdenum film before (dots with no fill) and (filled dots) after one cycle of thermal oxidation and wet-chemistry oxide dissolution, with a preceding pre-clean step. The greater molybdenum loss of the molybdenum film enabled by a pre-clean may be readily observed in FIG. 5b. In both examples, the thermal oxidation was performed at 180° C. for 30 seconds in 100 g/m³ O₃ ambient with 18 SLM. The pre-cleaning as well as the dissolution step was performed in dNH4OH (dilution 1:100) for 30 seconds.

FIG. 6 compares roughness of a molybdenum surface with an initial roughness (“REFERENCE”) resulting after wet oxidation in acidified ozonated water, thermal oxidation in O₃, and a full recess sequence of thermal oxidation followed by oxide dissolution, respectively. As may be observed, there is a decrease of roughness after thermal oxidation compared to the reference. At a temperature of 180° C. surface roughness is relatively insensitive to duration and O₃ concentration and flow rate. There is a further additional decrease of roughness after the full recess sequence, compared to oxidation only. Increasing the number of cycles from 3 to 6 yields a further reduction of roughness. Wet oxidation in acidified ozonated water results in significant roughness increase.

FIG. 7 illustrates recess amount of ALD and PVD molybdenum films as a function of number of cycles of thermal oxidation (bake in a 100 g/m³ O₃ ambient at 180° C. for 30 seconds) followed by oxide dissolution (in dNH₄OH in a 1:100 dilution for 30 seconds). As may be seen there is an approximately linear relation between recess amount and number of cycles. There is no significant difference of recess amount for the different deposition methods.

In the above the inventive concept has mainly been described with reference to a limited number of examples. However, as is readily appreciated by a person skilled in the art, other examples than the ones disclosed above are equally possible within the scope of the inventive concept, as defined by the appended claims.

1. A method for etching a molybdenum feature, comprising the steps of:
a) oxidizing a thickness portion of the molybdenum feature using a thermal oxidation process to form a thermal molybdenum oxide layer, and b) dissolving the thermal molybdenum oxide layer using a wet chemistry.

2. A method according to claim 1, wherein an oxidizing ambient of the thermal oxidation process comprises O₃.

3. A method according to claim 2, wherein the thermal oxidation process comprises heating the molybdenum feature to a temperature of at least 150° C.

4. A method according to claim 2, wherein the thermal oxidation process comprises heating the molybdenum feature to a temperature in a range from 180 to 300° C.

5. A method according to claim 2, wherein an O₃ concentration is at least 50 g/m³.

6. A method according to claim 2, wherein an O₃ concentration is in a range from 100 to 200 g/m³.

7. A method according to claim 2, wherein an O₃ flow rate is at least 5 SLM.

8. A method according to claim 2, wherein an O₃ flow rate is in a range from 18 to 20 SLM.

9. A method according to any to claim 2, wherein the molybdenum feature is subjected to the oxidizing ambient for a duration of at least 30 seconds.

10. A method according to claim 1, wherein an oxidizing ambient of the thermal oxidation process comprises O₂.

11. A method according to claim 10, wherein the thermal oxidation process comprises heating the molybdenum feature to a temperature of at least 200° C.

12. A method according to claim 1, wherein the wet chemistry is a water-comprising liquid removing the thermal molybdenum oxide selectively to molybdenum.

13. A method according to claim 12, wherein the wet chemistry is selected from DIW, an alkaline solution, an ammonia solution or an aqueous solution of CO₂W, HF or HCl.

14. A method according to claim 1, further comprising repeating a sequence of steps a) and b) a number of times.

15. A method according to claim 1, further comprising a step of pre-cleaning to remove potential contamination and the native oxide from the molybdenum feature prior to performing steps a) and b).

16. A method according to claim 1, wherein step a) comprises oxidizing the thickness portion of the molybdenum feature using the thermal oxidation process until the thermal molybdenum oxide layer reaches a self-limited thickness.

17. A method according to claim 16, wherein the self-limited thickness is 6 nm or less.
